(19) United States
(12) Patent Application Publication
(10) Pub. No.: US 2026/0173652 A1
(43) Pub. Date: Jun. 18, 2026

(54) TRANSISTOR AND DISPLAY DEVICE INCLUDING THE SAME

(71) Applicant: LG Display Co., Ltd., Seoul (KR)

(72) Inventors: Jang Dae KIM, Paju-si (KR); Seung Chan CHOI, Paju-si (KR); Tae Hyoung MOON, Paju-si (KR); Sang Soon NOH, Paju-si (KR)

(73) Assignee: LG Display Co., Ltd., Seoul (KR)

(21) Appl. No.: 19/349,068

(22) Filed: Oct. 3, 2025

(30) Foreign Application Priority Data
Dec. 17, 2024 (KR) 10-2024-0188821

(51) Int. Cl. H10K 59/121

(52) U.S. Cl. CPC H10K 59/1213

(57) ABSTRACT

A display device may include a substrate, an active area, a non-active area, a transistor disposed at least in the active area and including a gate electrode, a source electrode, a drain electrode, and an active layer, and a gate insulating film disposed between the gate electrode and the active layer. The active layer may include a lower semiconductor layer positioned adjacent to the substrate and having a channel region and source-drain regions positioned at both sides of the channel region interposed therebetween, an upper semiconductor layer positioned on the lower semiconductor layer adjacent to the gate electrode, and a fine insulating film positioned between the lower semiconductor layer and the upper semiconductor layer. The upper semiconductor layer may include an opening in a portion overlapping the gate electrode. The fine insulating film and the gate insulating film may contact each other through the opening.

### CROSS-REFERENCE TO RELATED APPLICATIONS

This application claims the benefit of and priority to Korean Patent Application No. 10-2024-0188821, filed on Dec. 17, 2024, the entire contents of which are incorporated herein by reference for all purposes as if fully set forth herein.

### BACKGROUND

### 1. Technical Field

The present disclosure relates to a transistor and a display device including the same.

### 2. Description of Related Art

Display devices that display images such as TVs, monitors, smartphones, tablets, and laptops are being used in various ways and forms.

Display devices include a display panel including a plurality of light emitting elements or liquid crystals to display images and a transistor to control the operation of each of the light emitting elements or liquid crystals, to display a desired image through the light emitting elements or liquid crystals.

Display devices include a plurality of pixels including light emitting elements and thus include a plurality of driving and switching elements to drive and control the light emitting elements provided in the respective pixels. The driving and switching elements may include transistors.

Recently, various research and developments is being conducted to improve the performance and reliability of transistors.

The description of related art should not be considered prior art merely because it is mentioned in or associated with this section. The description of related art includes information that describes one or more aspects of the subject technology, and the description in this section does not limit the scope of the invention.

### SUMMARY

Accordingly, one or more aspects of the present disclosure are directed to a transistor and a display device including the same that substantially obviate one or more problems due to limitations and disadvantages of the related art.

An aspect of the present disclosure is to provide a transistor with improved reliability and a display device including the same.

Another aspect of the present disclosure is to provide a structure in which defects in a semiconductor layer functioning as a channel in a transistor and a display device are minimized.

Another aspect of the present disclosure is to provide a structure in which an offset area of a semiconductor layer functioning as a channel in a transistor and a display device is minimized and a channel area is maximized.

A further another aspect of the present disclosure is to provide a structure in which ESG (Environmental, Social and Governance) is realized by improving the reliability of a transistor and a display device and reducing power consumption.

Additional advantages, aspects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these aspects and other advantages and in accordance with the purpose of the disclosure, as embodied and broadly described herein, a display device includes a substrate, an active area, a non-active area, a transistor disposed at least in the active area and including a gate electrode, a source electrode, a drain electrode, and an active layer, and a gate insulating film disposed between the gate electrode and the active layer, wherein the active layer includes a lower semiconductor layer positioned adjacent to the substrate and having a channel region and source-drain regions positioned at both sides of the channel region interposed therebetween, an upper semiconductor layer adjacent to the gate electrode and positioned on the lower semiconductor layer, and a fine insulating film positioned between the lower semiconductor layer and the upper semiconductor layer, wherein the upper semiconductor layer includes an opening in a portion overlapping the gate electrode, and the fine insulating film and the gate insulating film contact each other through the opening.

The upper semiconductor layer may overlap the source-drain regions of the lower semiconductor layer and may be not disposed in the opening.

A width of the opening may be smaller than a width of the gate electrode.

An end of the upper semiconductor layer adjacent to the opening may overlap the gate electrode.

A thickness of the fine insulating film may be less than a thickness of the lower semiconductor layer and a thickness of the upper semiconductor layer.

The thickness of the fine insulating film may be less than a thickness of the gate insulating film.

The thickness of the lower semiconductor layer may be greater than the thickness of the upper semiconductor layer.

The fine insulating film may contain a dielectric material.

The fine insulating film may contain at least one of silicon oxide (SiOx) and silicon oxynitride (SiOxNy).

The end of the upper semiconductor layer adjacent to the opening may be inclined.

A distance from an upper surface of the fine insulating film exposed to the opening to the gate electrode may be less than a distance from the upper surface of the fine insulating film positioned outside the gate electrode to an upper surface of the gate insulating film.

The source electrode and the drain electrode penetrate the upper semiconductor layer and the fine insulating film, and contact the source-drain regions of the lower semiconductor layer.

The upper semiconductor layer and the lower semiconductor layer may include an oxide semiconductor.

The transistor may be further disposed in the non-active area of the substrate.

In another aspect of the present disclosure, a transistor includes an active layer, a gate electrode overlapping the active layer, a gate insulating film disposed between the active layer and the gate electrode, and a source electrode and a drain electrode contacting source-drain regions of the active layer, wherein the active layer includes a lower semiconductor layer positioned adjacent to a substrate, an upper semiconductor layer positioned adjacent to the gate electrode, and a fine insulating film disposed between the lower semiconductor layer and the upper semiconductor layer, and wherein the upper semiconductor layer includes an opening in a portion overlapping the gate electrode, and the fine insulating film and the gate insulating film contact each other through the opening.

The upper semiconductor layer may overlap the source-drain regions of the lower semiconductor layer and may be not disposed in the opening.

A width of the opening may be less than a width of the gate electrode.

An end of the upper semiconductor layer adjacent to the opening may overlap the gate electrode.

A thickness of the fine insulating film may be less than a thickness of the lower semiconductor layer and the thickness of the fine insulating film is less than a thickness of the upper semiconductor layer.

The source electrode and the drain electrode may penetrate the upper semiconductor layer and the fine insulating film, and contact the source-drain regions of the lower semiconductor layer.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 illustrates an example of a display device applicable to the present disclosure;

FIGS. 2(a) and 2(b) illustrate examples of an equivalent circuit for a subpixel SP applicable to the display device of the present disclosure;

FIG. 3(a) illustrates an example of the structure of a transistor provided in an active area of a display device of the present disclosure;

FIG. 3(b) is an example graph illustrating a dopant concentration depending on the area of a lower semiconductor layer shown in FIG. 3(a);

FIG. 4 illustrates the relationship between the gate electrode, the lower semiconductor layer, the fine insulating film, and the upper semiconductor layer of the transistor shown in FIG. 3(a); and

FIG. 5 illustrates an example in which the transistor illustrated with reference to FIGS. 3(a) and 4 is applied to a display device.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference will now be made in detail to the various embodiments of the present disclosure, examples of which are illustrated in the accompanying drawings.

Like reference numbers refer to like components throughout the description of the figures. The thickness, ratio, size, and the like of components shown in the drawings to illustrate various embodiments of the present disclosure are exaggerated for better illustration. The scale of the components shown in the drawings is different from the actual scale for better illustration and is therefore not limited to the scale shown in the drawings.

It will be understood that, when an element (or a region, layer, part or the like) is referred to as being “on”, “connected to” or “bonded to” another element, it may be directly on, connected to or bound to the other element, or an intervening element may also be present therebetween.

The term “and/or” includes all of one or more combinations that may be defined by the associated components.

In describing the variety of embodiments of the present disclosure, terms such as “first” and “second” may be used to describe a variety of components, but these terms only aim to distinguish the same or similar components from one another. Accordingly, throughout the disclosure, a “first” component may be referred to as a “second” component within the technical concept of the present disclosure. Similarly, a “second” component may be referred to as a “first” component within the technical concept of the present disclosure. Singular forms are intended to include plural forms as well, unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

The terms such as “below”, “beneath”, “above” and “upper” are used to describe the relationships between components shown in the drawings. The terms are relative concepts and are described based on the directions indicated in the drawings. For example, unless “immediately” or “directly” is used, one or more other components may be located between two components. The spatially relative terms such as “below”, “beneath”, “lower”, “above” and “upper” may be used to easily describe the relationships between one element or component and another element or component as depicted in the drawings. Thus, for example, “below” and “lower” with respect to a first component may be in the opposite direction to “above” and “upper” with respect to the first component.

Spatially relative terms should be understood to include different orientations of elements when used or operated in addition to the orientation depicted in the drawings. For example, when elements depicted in the drawings are flipped over, an element described as “below” or “beneath” another element may be placed “above” the other element. Thus, the example term “below” may include both above and below.

It will be further understood that the terms “comprises” and/or “has”, when used herein, specify the presence of stated features, integers, steps, operations, elements, components or combinations thereof, but do not preclude the presence or addition of one or more other features, integers, steps, operations, elements, components, or combinations thereof.

Features of various embodiments of the present disclosure may be partially or completely integrated or combined with each other, and may be variously interoperated with each other and driven technically. The embodiments of the present disclosure may be carried out independently from each other, or may be carried out together in an interrelated manner.

Hereinafter, the display device of the present disclosure will be described with reference to the attached drawings and embodiments as follows.

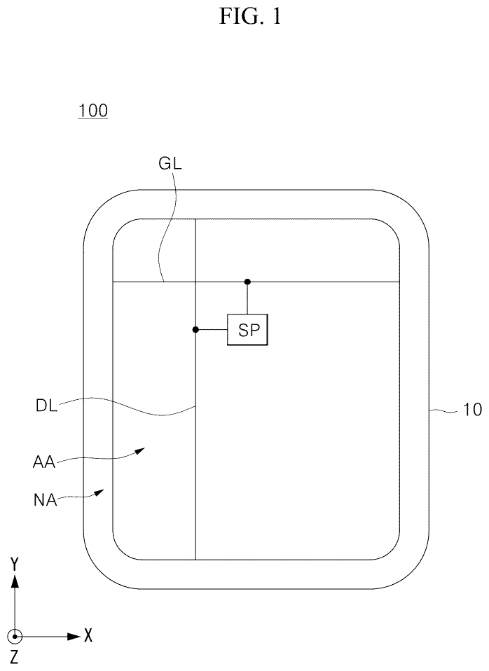

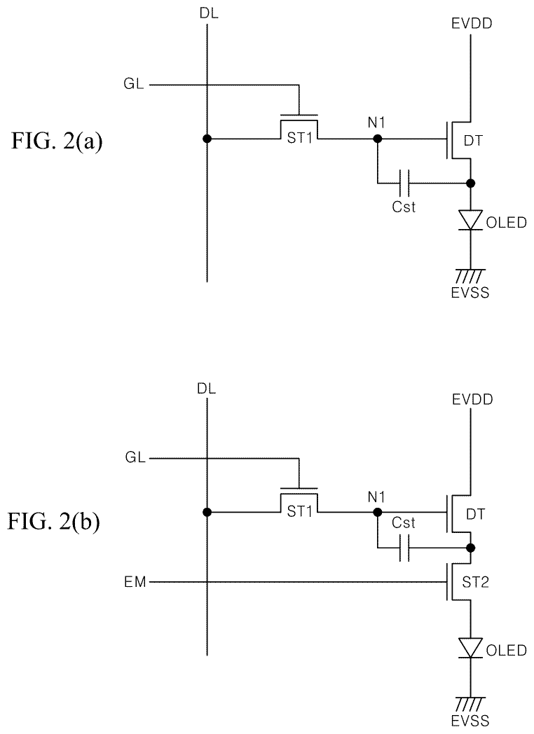

FIG. 1 illustrates an example of a display device applicable to the present disclosure, and FIGS. 2(a) and 2(b) illustrate examples of an equivalent circuit for a subpixel SP applicable to the display device of the present disclosure.

Referring to FIGS. 1, 2(a) and 2(b), the display device according to an example of the present disclosure includes a display panel 10 and the display panel 10 may include an active area AA and a non-active area NA.

The active area AA may be an area for displaying an image. A plurality of subpixels SP may be disposed in the active area AA of the display panel 10 and an image may be displayed using the subpixels SP. The area where the subpixels SP are disposed may correspond to an active area AA and an area other than the active area AA may correspond to a non-active area NA.

The non-active area NA may be disposed in an edge area surrounding the active area AA where an image is displayed. At least one driving unit to drive a plurality of subpixels SP may be disposed in the non-active area NA. The driving unit may be a gate in-panel (GIP).

Various additional elements may be further disposed in the non-active area NA to drive the subpixels SP in the active area AA.

At least one subpixel SP may include, for example, a circuit including a first switching transistor ST1, a driving transistor DT, a capacitor Cst, or a light emitting element OLED, as shown in FIG. 2(a) or FIG. 2(b).

A first electrode (e.g., a drain electrode) of the first switching transistor ST1 may be electrically connected to a data line DL, a second electrode (e.g., a source electrode) may be electrically connected to a first node N1, and a gate electrode of the first switching transistor ST1 may be electrically connected to a gate line GL. The first switching transistor ST1 may transmit a data signal supplied through the data line DL to the first node N1 in response to a scan signal supplied through the gate line GL.

The capacitor Cst may be electrically connected to the first node N1 and may be charged with a voltage applied to the first node N1.

The first electrode (e.g., the drain electrode) of the driving transistor DT may receive a high-potential driving voltage EVDD, and the second electrode (e.g., the source electrode) may be electrically connected to the first electrode (e.g., the anode) of the light emitting element OLED. The driving transistor DT may control the amount of driving current flowing to the light emitting element OLED in response to the voltage applied to the gate electrode.

The active layer of the first switching transistor ST1 and/or the driving transistor DT may contain oxide such as indium-gallium-zinc-oxide (IGZO), but is not limited thereto.

The light emitting element OLED may output light corresponding to the driving current. The light emitting element OLED may output light of one of the colors of red (R), green (G), blue (B), and white (W).

The light emitting element OLED may include an anode, a light emitting layer disposed on the anode, and a cathode supplying a common voltage. The light emitting layer may be realized to emit light of the same color for each pixel, such as white light, or may be realized to emit different colors for the respective subpixels SP, such as red (R), green G, and blue (B) light.

The light emitting element OLED may be a top-emission diode or a bottom-emission diode.

FIG. 2(a) illustrates an example in which the driving transistor DT is directly connected to the light emitting element OLED, but the present disclosure is not limited thereto. As shown in FIG. 2(b), the driving transistor DT may be connected to the light emitting element OLED via a second switching transistor ST2.

Specifically, as shown in FIG. 2(b), the second switching transistor ST2 may be disposed between the driving transistor DT and the light emitting element OLED, a first electrode of the second switching transistor ST2 may be connected to the driving transistor DT, and a second electrode of the second switching transistor ST2 may be electrically connected to the light emitting element OLED. In response to a light emitting signal applied to the gate electrode of the driving transistor DT, on/off of the driving current applied from the driving transistor DT to the light emitting element OLED may be controlled.

In addition, although not shown in FIGS. 2(a) and 2(b), a compensation circuit (not shown) for compensating for a threshold voltage of the driving transistor DT, which is a driving transistor, may be further provided within the subpixel SP. The compensation circuit may include at least one transistor connected to the driving transistor DT and may be provided in the subpixel SP.

Depending on the configuration mode, the compensation circuit may have various configurations, such as 3T1C including three transistors and one capacitor Cst within the subpixel SP, or 4T2C including four transistors and two capacitors Cst, or 5T2C, 6T1C, 6T2C, 7T1C, 7T2C, or the like.

Meanwhile, when the defects of the active layer in each transistor constituting the circuit of the subpixel as shown in FIG. 2(a) or 2(b) is minimized and the channel region has a sufficient length, it may be stably driven and as a result, the reliability of the transistor and the display device may be improved and the power consumption may be reduced.

To this end, the transistor of the present disclosure may include a fine insulating film within the active layer and the fine insulating film may reduce defects in the lower semiconductor layer where a channel is substantially formed within the active layer. Such a fine insulating film may perform hydrogen (H) gettering, thereby minimize the influence of hydrogen (H) on the lower semiconductor layer.

In addition, the removal of hydrogen (H) disposed in the fine insulating film overlapping an opening may be maximized by providing an upper semiconductor layer on top of the fine insulating film and the opening where the upper semiconductor layer is not disposed is included in the portion overlapping the gate electrode. This may reduce the deterioration of the transistor and enhance reliability.

In addition, the upper semiconductor layer positioned in the portion overlapping a source-drain region of the lower semiconductor layer may minimize the length of the offset region caused by the diffusion of hydrogen into the lower semiconductor layer by blocking hydrogen (H) coming down from the upper portion during the subsequent heat treatment process.

As such, the transistor of the present disclosure having a fine insulating film may be disposed in a GIP driving circuit that is provided in a bezel area, which is a non-active area NA of the panel, to supply a scan signal to the pixel circuit, in addition to the pixel circuit described above.

Hereinafter, an example of a transistor having a fine insulating film will be described in detail.

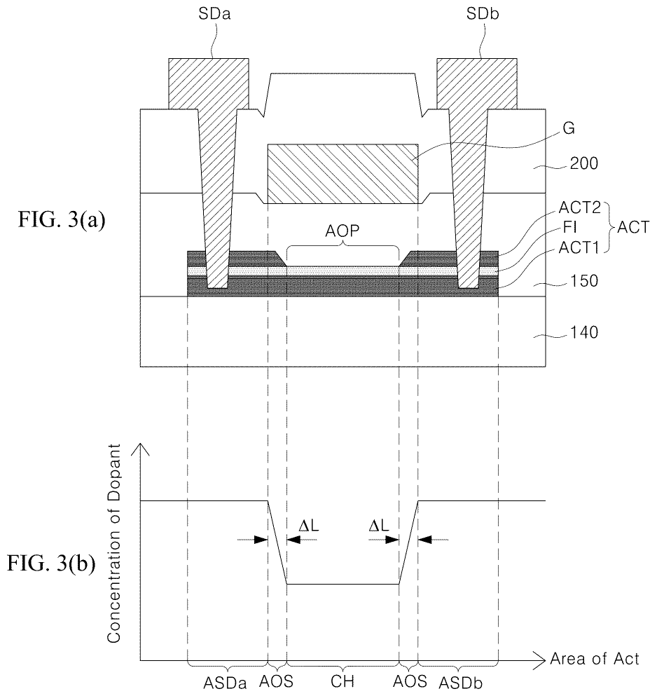

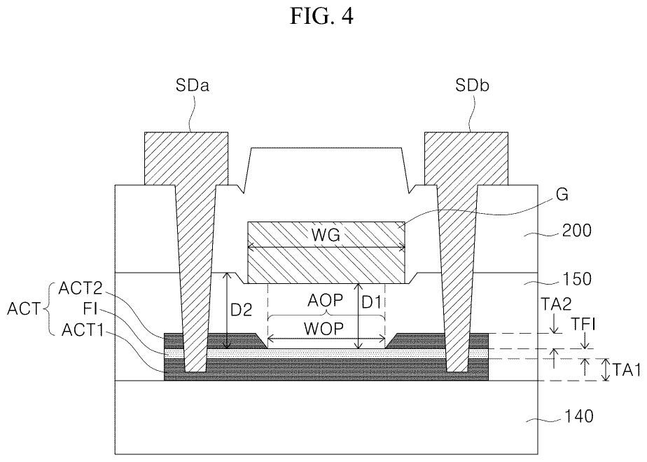

FIG. 3(a) illustrates an example of the structure of a transistor provided in an active area of a display device of the present disclosure, and FIG. 4 is a diagram specifically illustrating the relationship between the gate electrode, the lower semiconductor layer, the fine insulating film, and the upper semiconductor layer of the transistor shown in FIG. 3(a).

FIG. 3(a) illustrates an example of a cross-section of a transistor according to the present disclosure, and FIG. 3(b) is an example graph illustrating a dopant concentration depending on the area of the lower semiconductor layer ACT1 in FIG. 3(a).

As shown in FIG. 3(a), the transistor of the present disclosure may include an active layer ACT, a gate electrode G, a source electrode SDa, and a drain electrode SDb, a buffer layer 140 may be disposed under the active layer ACT, a gate insulating film 150 may be disposed between the gate electrode G and the active layer ACT, and an interlayer insulating film 200 may be disposed on the gate electrode G.

In FIGS. 3(a) and 4, the active layer ACT is disposed on the buffer layer 140 and the substrate (not shown) is omitted, but the buffer layer 140 may be disposed adjacent to the substrate and the following description will be provided on the assumption that the buffer layer 140 is disposed adjacent to the substrate.

As shown in FIGS. 3(a) and 4, the active layer ACT may have a channel region CH and source-drain regions ASDa and ASDb on both sides of the channel region CH.

The active layer ACT may be disposed on the buffer layer 140, may include an oxide semiconductor, and may have a channel region CH and source-drain regions ASDa and ASDb. Here, the source-drain regions ASDa and ASDb have higher electrical conductivity than the channel region CH, and may thus be referred to as “conductive regions”.

The oxide semiconductor material contained in the active layer ACT may, for example, include at least one of an IZO (InZnO)-based, an IGO (InGaO)-based, an ITO (InSnO)-based, an IGZO (InGaZnO)-based, an IGZTO (InGaZnSnO)-based, a GZTO (GaZnSnO)-based, a GZO (GaZnO)-based, an ITZO (InSnZnO)-based, or a FIZO (FeInZnO)-based oxide semiconductor material.

The active layer ACT of the present disclosure may include, as shown in FIGS. 3(a) and 4, a lower semiconductor layer ACT1, an upper semiconductor layer ACT2, and a fine insulating film FI.

Each of the lower semiconductor layer ACT1 and the upper semiconductor layer ACT2 may be provided as a single film or a multilayer film.

For example, each of the lower semiconductor layer ACT1 and the upper semiconductor layer ACT2 may be provided as a single film including an IGZO (InGaZnO)-based oxide semiconductor, or may be provided as a multilayer film including an IGZO (InGaZn O)-based oxide semiconductor, but having different content ratios for indium (In), gallium (Ga), and zinc (Zn).

Alternatively, each of the lower semiconductor layer ACT1 and the upper semiconductor layer ACT2 may be provided as a single film including any one oxide semiconductor material of IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, ITZO (InSnZnO)-based, and FIZO (FeInZnO)-based oxide semiconductor materials, or may be provided as a multilayer film having at least two different oxide semiconductor materials.

The lower semiconductor layer ACT1 included in the active layer ACT of the present disclosure may function as a channel and the fine insulating film FI may function to improve the reliability of the transistor by minimizing defects of the lower semiconductor layer ACT1 during the transistor manufacturing process, and the upper semiconductor layer ACT2 may function to block hydrogen (H) during the transistor manufacturing process. A detailed description of the lower semiconductor layer ACT1, the upper semiconductor layer ACT2 and the fine insulating film FI will be given with reference to FIG. 4 after detailed description of the basic structure of the transistor.

In the present disclosure, the lower semiconductor layer ACT1 may function as a channel and the lower semiconductor layer ACT1 may be provided with a channel region CH, source-drain regions ASDa and ASDb, and an offset region AOS.

In the lower semiconductor layer ACT1, the channel region CH may be positioned at a portion overlapping the gate electrode G, as shown in FIG. 3(b), and the source-drain regions ASDa and ASDb may be positioned at both outer sides of the channel region CH. The source-drain regions ASDa and ASDb may be positioned at one side and the other side of the channel region CH and may have a higher dopant concentration than the channel region CH. An offset region AOS may be provided between each source-drain regions ASDa and ASDb and the channel region CH. The dopant concentration of the offset region AOS may gradually decrease from each of source-drain regions ASDa and ASDb to the channel region CH.

The channel region CH may have a lower dopant (e.g., boron (B)) concentration than the source-drain regions ASDa and ASDb, and may have an electrical conductivity corresponding to the voltage applied to the gate electrode G, and may include a channel through which carriers move depending on the voltage applied to the gate electrode G.

The source-drain regions ASDa and ASDb in the lower semiconductor layer ACT1 may have a higher dopant concentration than the channel region CH, as shown in FIG. 3(b), and may be a conductive region with high electrical conductivity. The source-drain regions ASDa and ASDb may be formed through a conductive process in which a dopant is injected into a part of the active layer ACT and through a subsequent heat treatment process in which an interlayer insulating film 200, or the like, is formed after the conductive process. The conductive region may be formed as the source-drain regions ASDa and ASDb of the transistor.

The initial length of the channel region CH may be determined by the conductive process of injecting a dopant into the active layer ACT after the gate electrode G is patterned on the active layer ACT, and then the final effective length of the channel region CH may be determined by diffusing a part of the dopant or a part of the hydrogen by ΔL through the subsequent heat treatment process. The initial distribution of the threshold voltage Vth of the transistor may be controlled depending on the final effective length of the channel region CH. The ΔL region that contacts the channel region CH in the conductive region (ASDa, ASDb) and where the concentration of the dopant changes may be formed as an offset region.

The gate electrode G may be spaced apart from the active layer ACT and overlap the channel region CH. The gate electrode G may be controlled to form a channel in the channel region CH of the active layer ACT through an applied voltage.

The gate electrode G may include a conductive material, for example, a metal such as aluminum (Al), chromium (Cr), copper (Cu), titanium (Ti), molybdenum (Mo), or tungsten (W).

The source electrode SDa and the drain electrode SDb may be electrically connected to the source-drain regions ASDa and ASDb, respectively. The source electrode SDa may be in contact with the first source-drain region ASDa and the drain electrode SDb may be in contact with the second source-drain region ASDb.

The active layer ACT may be disposed on the buffer layer 140, a gate insulating film 150 may be disposed between the active layer ACT and the gate electrode G, and an interlayer insulating film 200 covering the gate electrode G may be disposed on the gate insulating film 150.

The source electrode SDa and the drain electrode SDb may penetrate the interlayer insulating film 200 and contact the source-drain regions ASDa and ASDb provided in the active layer ACT. The source electrode SDa and the drain electrode SDb may be electrically connected to a driving transistor or another switching transistor in the pixel circuit or an external circuit element.

The buffer layer 140 may be disposed on the substrate and may include an inorganic insulating material such as silicon oxide (SiO) and silicon nitride (SiN). The buffer layer 140 may insulate a metal layer such as a light-shielding pattern (not shown) disposed on the substrate from the active layer ACT.

The gate insulating film 150 may be disposed between the gate electrode G and the active layer ACT to insulate between the gate electrode G from the active layer ACT. The gate insulating film 150 may include at least one of silicon oxide (SiOx), silicon nitride (SiNx), and silicon oxynitride (SiOxNy). For example, silicon oxide (SiOx) may include silicon dioxide (SiO₂).

The interlayer insulating film 200 may be disposed on the gate insulating film 150 to cover the gate electrode G and may extend along the gate insulating film 150. The interlayer insulating film 200 may include an insulating material such as silicon oxide (SiOx) or silicon oxynitride (SiOxNy).

The source electrode SDa and the drain electrode SDb may be disposed on the interlayer insulating film 200, penetrate the interlayer insulating film 200 and the gate insulating film 150, and may penetrate to a part of the lower semiconductor layer ACT1 to electrically contact the source-drain regions ASDa and ASDb.

Meanwhile, as shown in FIGS. 3(a) and 4, the active layer ACT in the transistor according to the present disclosure may include the lower semiconductor layer ACT1, the upper semiconductor layer ACT2, and the fine insulating film FI, as described above.

As shown in FIGS. 3(a) and 4, the lower semiconductor layer ACT1 may be positioned on the buffer layer 140 adjacent to the substrate and may have a channel region CH and source-drain regions ASDa and ASDb. For example, the lower semiconductor layer ACT1 may be formed by deposition thereof on the buffer layer 140 within the chamber.

The fine insulating film FI may be positioned on the lower semiconductor layer ACT1. That is, the fine insulating film FI may be positioned at between the lower semiconductor layer ACT1 and the upper semiconductor layer ACT2. The fine insulating film FI may have a low content of hydrogen (H) within the film and thus function to improve the reliability of the lower semiconductor layer ACT1 and protect the interface with the lower semiconductor layer ACT1.

The fine insulating film FI may be continuously deposited on the entire surface of the lower semiconductor layer ACT1 within the chamber without external exposure (vacuum break). Accordingly, defects at the interface between the lower semiconductor layer ACT1 and the fine insulating film FI may be minimized.

The fine insulating film FI may include a dielectric material and the fine insulating film FI may, for example, include at least one of silicon oxide (SiOx) and silicon oxynitride (SiOxNy).

The upper semiconductor layer ACT2 may be positioned on the lower semiconductor layer ACT1 adjacent to the gate electrode G. The upper semiconductor layer ACT2 may be spaced apart from the lower semiconductor layer ACT1. For example, the upper semiconductor layer ACT2 may be formed over the entire surface of the fine insulating film FI in the chamber by deposition and heat treatment. Then, a part of the upper semiconductor layer ACT2 may be etched to form an opening AOP.

The upper semiconductor layer ACT2 may getter hydrogen (H) contained in the fine insulating film FI during the heat treatment process after deposition, thereby reducing hydrogen (H) in the fine insulating film FI. After the opening AOP is formed in some portion of the upper semiconductor layer ACT2, the upper semiconductor layer ACT2 positioned outside the opening AOP may suppress the diffusion of hydrogen (H) during the subsequent heat treatment process after forming the interlayer insulating film 200, thereby suppressing the diffusion of hydrogen into the lower semiconductor layer ACT1.

The opening AOP may be positioned in a part of the upper semiconductor layer ACT2 that overlaps the gate electrode G. That is, the part of the upper semiconductor layer ACT2 that overlaps the gate electrode G may include an opening AOP where the upper semiconductor layer ACT2 is not positioned, and the upper semiconductor layer ACT2 may be positioned in a part that does not overlap the gate electrode G. Accordingly, the fine insulating film FI and the gate insulating film 150 may contact each other through the opening AOP.

The opening AOP may be formed by etching and removing a part of the upper semiconductor layer ACT2 that overlaps the gate electrode G (or the portion that overlaps the channel region CH of the lower semiconductor layer ACT1) after the upper semiconductor layer ACT2 is deposited on the fine insulating film FI.

The etching process of the upper semiconductor layer ACT2 to form the opening AOP may be performed by (1) using a half tone mask or (2) applying a photoresist (PR) to the portion where the upper semiconductor layer ACT2 will remain and then etching a part corresponding to the opening AOP.

Through the opening AOP forming process, the upper semiconductor layer ACT2 may remain on the outside of the channel region CH of the lower semiconductor layer ACT1, that is, on the source-drain regions ASDa and ASDb, and the upper semiconductor layer ACT2 may have an inclined surface in the opening AOP. That is, the end of the upper semiconductor layer ACT2 adjacent to the opening AOP may be inclined.

The upper semiconductor layer ACT2 is deposited on top of the fine insulating film FI and then heat-treated, so that the oxide of the upper semiconductor layer ACT2 may be bonded to hydrogen (H) positioned within the fine insulating film FI. As such, the upper semiconductor layer ACT2 may getter hydrogen within the fine insulating film FI.

Then, when, in the process of forming the opening AOP, a part of the upper semiconductor layer ACT2 is removed to form the opening AOP, the hydrogen (H) of the fine insulating film FI that was bonded to the oxide of the upper semiconductor layer ACT2 is also removed so that the amount of hydrogen (H) contained in the fine insulating film FI may be minimized.

Accordingly, the present disclosure may minimize hydrogen (H) in a region overlapping the channel region CH in the fine insulating film FI by providing an opening AOP in the upper semiconductor layer ACT2. As a result, it is possible to minimize defects at the interface of the lower semiconductor layer ACT1 contacting the fine insulating film FI, to reduce deterioration of the transistor element, and to enhance reliability.

Then, a gate insulating film 150 may be formed to cover the upper surface and side surface of the upper semiconductor layer ACT2, the upper surface and side surface of the fine insulating film FI exposed through the opening AOP, the side surface of the lower semiconductor layer ACT1, and the upper surface of the buffer layer 140. Accordingly, the fine insulating film FI and the gate insulating film 150 may contact each other through the opening AOP.

The gate insulating film 150 formed on the upper side of the fine insulating film FI may have a thickness difference due to the upper semiconductor layer ACT2 positioned outside the opening AOP. Accordingly, the distance D1 from the upper surface of the fine insulating film FI exposed to the opening AOP to the gate electrode G may be smaller than the distance D2 from the upper surface of the fine insulating film FI positioned outside the gate electrode G to the upper surface of the gate insulating film 150.

Then, the gate electrode G may be formed on top of the gate insulating film 150. The gate electrode G may overlap the opening AOP and the width WG of the gate electrode G may be larger than the width WOP of the opening AOP. The end of the upper semiconductor layer ACT2 adjacent to the opening AOP may overlap the gate electrode G. In other words, the end of the upper semiconductor layer ACT2 may protrude inwardly from the end of the gate electrode G.

In a state in which the gate electrode G is provided on the gate insulating film 150, a conductive process of injecting a dopant into the upper semiconductor layer ACT2 and the lower semiconductor layer ACT1 may be performed. Through the conductive process, the dopant may be injected into the upper semiconductor layer ACT2 and the lower semiconductor layer ACT1 positioned on the outside of the gate electrode G.

Then, a subsequent heat treatment process to deposit and heat-treat an interlayer insulating film 200 on the gate electrode G and the gate insulating film 150 may be performed. Accordingly, a channel region CH, source-drain regions ASDa and ASDb and an offset region may be formed in the lower semiconductor layer ACT1. An upper semiconductor layer ACT2 may overlap the upper portion of the source-drain regions ASDa and ASDb, the upper portion of the channel region CH may overlap the opening AOP and thus the upper semiconductor layer ACT2 is not positioned in the opening AOP.

Hydrogen contained in the interlayer insulating film 200 may be diffused through the subsequent heat treatment process and diffused toward the lower semiconductor layer ACT1 through the gate insulating film 150.

The upper semiconductor layer ACT2 may be positioned above the source-drain regions ASDa and ASDb to prevent hydrogen (H) from diffusing into the lower semiconductor layer ACT1 during the subsequent heat treatment process. Accordingly, diffusion of hydrogen from the lower semiconductor layer ACT1 into the lower part of the gate electrode G may also be minimized.

According to the present disclosure, it is possible to suppress the diffusion of hydrogen in the lower semiconductor layer ACT1 using the upper semiconductor layer ACT2, thereby minimizing the length L of the offset region AOS formed in the lower semiconductor layer ACT1 and imparting a sufficient length to the channel region CH. This may improve the reliability of a short channel transistor in which the channel region CH is relatively small.

After the interlayer insulating film 200 is formed, a contact hole may be formed so as to form a source electrode SDa and a drain electrode SDb. The contact hole may penetrate the interlayer insulating film 200, the gate insulating film 150, the upper semiconductor layer ACT2, and the fine insulating film FI positioned on the outside of the gate electrode G to expose the lower semiconductor layer ACT1.

The source electrode SDa and the drain electrode SDb may be formed on the interlayer insulating film 200. Each of the source electrode SDa and the drain electrode SDb may penetrate the interlayer insulating film 200, the gate insulating film 150, the upper semiconductor layer ACT2, and the fine insulating film FI through the contact hole and may penetrate into a part of the lower semiconductor layer ACT1 and thus contact the source-drain regions ASDa and ASDb of the lower semiconductor layer ACT1.

Here, the lower semiconductor layer ACT1 may be formed to be the thickest among the active layers ACT so that the lower semiconductor layer ACT1 may sufficiently function as a channel layer. For example, the thickness TA1 of the lower semiconductor layer ACT1 may be greater than the thickness TFI of the fine insulating film FI and the thickness TA2 of the upper semiconductor layer ACT2.

In addition, FIGS. 3(a) and 4 illustrate an example in which the lower semiconductor layer ACT1 is formed as a single layer, but the lower semiconductor layer ACT1 may be formed as a multi-layer structure such as a double or triple layer structure.

The thickness TFI of the fine insulating film FI may be smaller than the thickness D1 of the gate insulating film 150 in the part overlapping the opening AOP. Since the gate insulating film 150 performs an insulating function, it requires a predetermined thickness or more to perform the insulating function. However, since the fine insulating film FI does not perform an insulating function, it may not require a thickness corresponding to the gate insulating film.

Here, the term “fine” in the fine insulating film FI may mean when the fine insulating film FI has a thickness smaller than the thickness D1 of the gate insulating film 150, as shown in FIG. 4. In addition, the upper semiconductor layer ACT2 may be positioned on a portion of the upper part of the fine insulating film FI, as shown in FIG. 4.

As shown in FIG. 4, in the present disclosure, the fine insulating film FI may be provided in the active layer ACT with a thickness smaller than the thickness D1 of the gate insulating film 150. Therefore, the thickness TFI of the fine insulating film FI may be smaller than the thickness of the active layer ACT. In addition, the thickness of the active layer ACT may be smaller than the thickness D1 of the gate insulating film 150.

For example, the thickness TFI of the fine insulating film FI may be smaller than the thickness TA1 of the lower semiconductor layer ACT1 and the thickness TA2 of the upper semiconductor layer ACT2. As a result, it is possible to minimize the hydrogen content of the fine insulating film FI and minimize the occurrence of defects at the interface between the fine insulating film FI and the lower semiconductor layer ACT1.

The thickness TA2 of the upper semiconductor layer ACT2 may be larger than the thickness TFI of the fine insulating film FI and may be smaller than the thickness TA1 of the lower semiconductor layer ACT1. According to the present disclosure, it is possible to maximize the amount of hydrogen gettered by the upper semiconductor layer ACT2 from the fine insulating film FI by adjusting the thickness TA2 of the upper semiconductor layer ACT2 to be larger than the thickness TFI of the fine insulating film FI. In addition, according to the present disclosure, it is possible to prevent the upper semiconductor layer ACT2 from being excessively large by adjusting the thickness TA2 of the upper semiconductor layer ACT2 to be smaller than the thickness TA1 of the lower semiconductor layer ACT1.

Hereinafter, an example in which the transistor described with reference to FIGS. 3(a) and 4 is applied to a display device will be described.

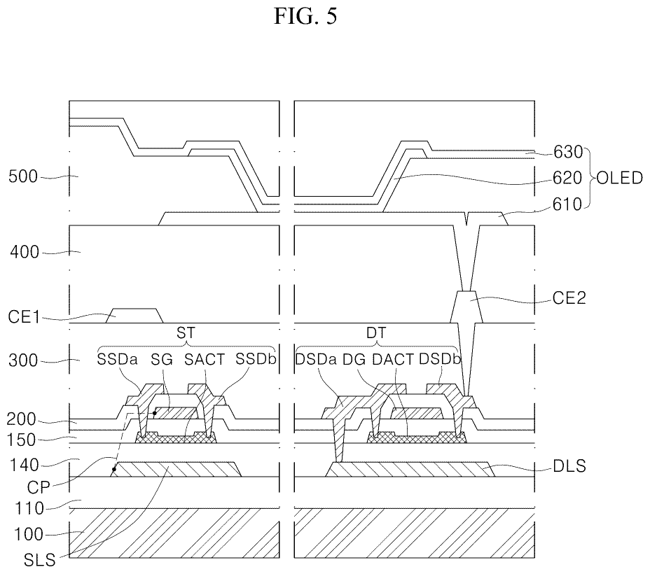

FIG. 5 illustrates an example in which the transistor illustrated with reference to FIGS. 3(a) and 4 is applied to a display device.

The cross-section of the display device in FIG. 5 is provided as an example of a configuration of a pixel equivalent circuit in which a driving transistor DT is electrically connected to a light emitting element OLED, as shown in FIG. 2(a). The present disclosure is not necessarily limited thereto. When the pixel equivalent circuit is configured as shown in FIG. 2(b), a switching transistor ST may be electrically connected to a light emitting element OLED. In FIG. 5, for the convenience of illustration, a configuration of a pixel equivalent circuit in which the driving transistor DT is electrically connected to the light emitting element OLED is provided as an example.

As shown in FIG. 5, the display device to which the switching transistor ST and the driving transistor DT are applied may include a substrate 100, a first insulating film 110, a buffer layer 140, a switching transistor ST, a first light-shielding pattern SLS, a driving transistor DT, a second light-shielding pattern DLS, a gate insulating film 150, an interlayer insulating film 200, a first planarizing film 300, a second planarizing film 400, first and second intermediate electrodes CE1 and CE2, a bank insulating film 500, and a light emitting element OLED. The cross-sectional structure of the display device in FIG. 5 is merely provided as an example for better understanding of the present disclosure and the present disclosure is not necessarily limited thereto.

The transistor of the present disclosure described with reference to FIGS. 3(a) and 4 may be applied to at least one of the switching transistor ST or the driving transistor DT. FIG. 5 illustrates an example in which the transistor of the present disclosure is applied to both the switching transistor ST and the driving transistor DT.

That is, as shown in FIG. 5, each active layer of the switching transistor ST and the driving transistor DT may include a lower semiconductor layer ACT1, a fine insulating film FI and an upper semiconductor layer ACT2, and the upper semiconductor layer ACT2 may include an opening AOP in a portion overlapping with the gate electrode, and the same transistor structure as shown in FIGS. 3(a) and 4 may be applied to the switching transistor ST and the driving transistor DT.

In FIG. 5, the description of the substrate 100, the buffer layer 140, the switching transistor ST, the first light-shielding pattern SLS, the driving transistor DT, the second light-shielding pattern DLS, the gate insulating film 150, the interlayer insulating film 200, and the first planarizing film 300 will focus on different characteristics from those described above to avoid repetition.

The substrate 100 may be formed of a flexible plastic material and thus may be flexible, and may also include a thin glass material having flexibility. The substrate 100 may be disposed in the active area AA and the non-active area NA of the display panel 10.

The substrate 100 may have a multilayer structure including an insulating material. For example, the substrate 100 may include a polymer material such as polyimide (PI) and an insulating material.

The first insulating film 110 may be disposed on the active area AA and the non-active area NA on the substrate 100. The first insulating film 110 may be referred to as a “buffer film”. The first insulating film 110 may be disposed on the substrate 100 to protect structures on the substrate 100 that are vulnerable to moisture penetration through the substrate 100 and to flatten the surface of the substrate 100. The first insulating film 110 may be formed as a single layer of an inorganic film or may be formed as a multilayer structure of a plurality of inorganic films. For example, the insulating film may include at least one inorganic film of a silicon oxide (SiOx) film, a silicon nitride (SiNx) film, and a silicon oxynitride (SiOxNy) film.

A first light-shielding pattern SLS to stabilize the driving characteristics of the switching transistor ST and a second light-shielding pattern DLS to stabilize the driving characteristics of the driving transistor DT may be disposed on the first insulating film 110.

A buffer layer 140 may be provided on the first insulating film such that it covers the first and second light-shielding patterns SLS and DLS. The buffer layer 140 may completely cover the active area AA of the substrate 100 and may include an insulating material. For example, the buffer layer 140 may include an inorganic insulating material such as silicon oxide (SiO) or silicon nitride (SiN), and may include a multilayer structure including the same material or different materials.

A switching transistor ST and a driving transistor DT may be disposed on the buffer layer 140. As shown in FIG. 5, when the switching transistor ST and the driving transistor DT are disposed on the same buffer layer 140, the process may be simplified, production energy may be reduced, greenhouse gas emissions that may be generated due to the manufacturing process may be reduced and thus ESG (environmental/social/governance) goals may be realized.

However, not all switching transistors ST and driving transistors DT are necessarily formed on the same buffer layer 140 and the present disclosure is not limited thereto.

The switching transistor ST may include a first gate electrode SG, a first active layer SACT, and a first source electrode SSDa and a first drain electrode SSDb, and the driving transistor DT may include a second gate electrode DG, a second active layer DACT, a second source electrode DSDa and a second drain electrode DSDb.

At least one first active layer SACT or second active layer DACT of the switching transistor ST and the driving transistor DT may include a lower semiconductor layer ACT1, a fine insulating film FI, and an upper semiconductor layer ACT2, as shown in FIGS. 3(a) and 4, and the upper semiconductor layer ACT2 may include an opening AOP in a portion overlapping the first gate electrode SG or the second gate electrode DG.

The buffer layer 140 may insulate the first active layer SACT of the switching transistor ST from the first light-shielding pattern SLS, and may insulate the second active layer DACT of the driving transistor DT from the second light-shielding pattern DLS.

The first gate electrode SG of the switching transistor ST may electrically contact the first light-shielding pattern SLS through the connection pattern CP. Accordingly, the first light-blocking pattern SLS may function as a bottom gate electrode and may further improve the response speed of the switching transistor ST.

Either the second source electrode DSDa or the second drain electrode DSDb of the driving transistor DT electrically contact the second light-blocking pattern DLS. Accordingly, the second light-blocking pattern DLS may more stably control the grayscale expression of the light emitting element OLED controlled by the driving transistor DT.

The gate insulating film 150 may insulate the first gate electrode SG of the switching transistor ST from the first active layer SACT, and insulate the second gate electrode DG of the driving transistor DT from the second active layer DACT.

The interlayer insulating film 200 may be disposed on the gate insulating film 150 such that it covers the first gate electrode SG of the switching transistor ST and the second gate electrode DG of the driving transistor DT. The first source electrode SSDa and the first drain electrode SSDb of the switching transistor ST and the second source electrode DSDa and the second drain electrode DSDb of the driving transistor DT may be disposed on the interlayer insulating film 200.

The first source electrode SSDa and the first drain electrode SSDb of the switching transistor ST may penetrate the interlayer insulating film 200 and the gate insulating film 150 and thus may contact the source-drain region (not shown) of the switching transistor ST, and the second source electrode DSDa and the second drain electrode DSDb of the driving transistor DT may penetrate the interlayer insulating film 200 and the gate insulating film 150 and thus contact the source-drain region (not shown) of the driving transistor DT.

The planarization film 300 or 400 may include an insulating material and may be disposed on the interlayer insulating film 200. The planarization film 300 or 400 may remove a step generated by the transistor within the subpixel SP. The planarization film 300 or 400 may have a flat upper surface and may include a material having high fluidity. For example, the planarization film 300 may include an organic insulating material.

The planarization film 300 or 400 may include a first planarization film 300 and a second planarization film 400. The first planarization film 300 and the second planarization film 400 may be sequentially laminated on the interlayer insulating film 200 to cover the first source electrode SSDa and the first drain electrode SSDb of the switching transistor ST and the second source electrode DSDa and the second drain electrode DSDb of the driving transistor.

The first planarization film 300 and the second planarization film 400 may remove the step caused by the driving circuit such as the switching transistor ST and the driving transistor DT. The upper surfaces of the first planarization film 300 and the second planarization film 400 may be flat surfaces and, for example, the upper surfaces of each of the first planarization film 300 and the second planarization film 400 facing the light emitting element OLED may be flat.

For this purpose, the first planarization film 300 and the second planarization film 400 may include a material having high fluidity. For example, the first planarization film 300 and the second planarization film 400 may include an organic insulating material. The second planarization film 400 may include a different material from the first planarization film 300. Accordingly, in the display device according to the embodiment of the present disclosure, the step caused by the driving circuits may be effectively eliminated.

The first and second intermediate electrodes CE1 and CE2 may be disposed between the first planarization film 300 and the second planarization film 400. The first and second intermediate electrodes CE1 and CE2 may include a conductive material. For example, the first and second intermediate electrodes CE1 and CE2 may include a metal such as aluminum (Al), chromium (Cr), copper (Cu), titanium (Ti), molybdenum (Mo), or tungsten (W).

The first intermediate electrode CE1 may electrically connect the switching transistor ST to the driving transistor DT, or electrically connect the switching transistor ST to another circuit component, although not shown.

The second intermediate electrode CE2 may electrically connect the driving transistor DT to the light emitting element OLED. For example, as shown in FIG. 5, the second intermediate electrode CE2 may electrically connect the second drain electrode DSDb of the driving transistor DT to the first electrode (anode, 610) of the light emitting element.

FIG. 5 illustrates an example in which the second drain electrode DSDb of the driving transistor DT contacts the first electrode (anode, 610) of the light emitting element OLED through the second intermediate electrode CE2, but the present disclosure is not necessarily limited thereto. When another switching transistor ST is provided between the driving transistor DT and the light emitting element as shown in FIG. 2(b), the driving transistor DT may be electrically connected to the light emitting element through the other switching transistor ST.

A bank insulating film 500 may be disposed on the second planarization film 400. The bank insulating film 500 may include an insulating material. For example, the bank insulating film 500 may include an organic insulating material. The bank insulating film 500 may include a different material from the first planarization film 300 and the second planarization film 400. The bank insulating film 500 may cover an edge of the first electrode (610, for example, an anode). The light emitting layer 620 and the second electrode (630, for example, a cathode) may be laminated on a portion of the first electrode 610 exposed by the bank insulating film 500. For example, the bank insulating film 500 may define a light emitting area in each subpixel SP.

A light emitting element OLED may be disposed in the light emitting region and the light emitting element OLED may include a first electrode 610, a light emitting layer 620, and a second electrode 630.

In the light emitting element OLED, the first electrode 610 may function as an anode, for example, and may include a conductive material. The first electrode 610 may have a high reflectivity. For example, the first electrode 610 may include a metal such as aluminum (Al) or silver (Ag). The first electrode 610 may have a multilayer structure. For example, the first electrode 610 may have a structure in which a reflective electrode formed of a metal is disposed between transparent electrodes formed of a transparent conductive material such as ITO and IZO.

The light emitting layer 620 may generate light having a brightness corresponding to the voltage difference between the first electrode 610 and the second electrode 630. For example, the light emitting layer 620 may include an emission material layer EML including an emission material. The emission material may include an organic material, an inorganic material, or a hybrid material. For example, the light emitting layer 620 may include an emission material layer containing an organic material.

The light emitting layer 620 may include at least one of a first light emitting common layer (not shown) disposed between the first electrode 610 and a second light emitting common layer (not shown) disposed between the second electrode 630. The first light emitting common layer (not shown) and the second light emitting common layer (not shown) may each include at least one of a hole injection layer HIL, a hole transport layer HTL, an electron transport layer ETL, and an electron injection layer EIL. The light emitting layer 620 may emit red (R), green G, or blue (B) light.

The second electrode 630 may, for example, function as a cathode and may include a conductive material. The second electrode 630 may include a different material from the first electrode 610. For example, the second electrode 630 may be a transparent electrode formed of a transparent conductive material such as ITO or IZO. The second electrode 630 may have a higher transmittance than the first electrode 610. Accordingly, light generated by the light emitting layer 620 in the display device according to the embodiment of the present disclosure may be emitted through the second electrode 630.

FIG. 5 illustrates the case where the structure of the active layer of the present disclosure is applied to a switching transistor ST and a driving transistor DT provided in a pixel, but the structure of the active layer of the present disclosure is not limited to being applied only to pixels.

That is, the transistor structure of the present disclosure may also be applied to a transistor provided in a GIP driving circuit that is provided in a bezel area, which is a non-active area NA of the panel, and supplies a scan signal to the pixel circuit.

Therefore, the transistor provided in the GIP driving circuit may also include an active layer including a lower semiconductor layer ACT1, a fine insulating film FI, and an upper semiconductor layer ACT2, the upper semiconductor layer ACT2 may include an opening AOP in a portion overlapping the gate electrode, and the transistor structure may be applied in the same manner as described with reference to FIGS. 3(a) and 4.

As such, in the embodiment of the present disclosure, the active layer includes the upper semiconductor layer ACT2, the fine insulating film FI, and the lower semiconductor layer ACT1, and the upper semiconductor layer ACT2 includes the opening AOP in the portion overlapping the gate electrode, thereby minimizing defects in the lower semiconductor layer ACT1 and reducing deterioration due to shallow traps.

Specifically, according to the embodiment of the present disclosure, by providing a fine insulating film FI formed without a vacuum break on the lower semiconductor layer ACT1, it is possible to minimize the formation of defects in the lower semiconductor layer ACT1 forming a channel region, thereby reducing deterioration due to traps and improving the reliability of the transistor.

According to the embodiment of the present disclosure, by disposing the end adjacent to the opening AOP in the upper semiconductor layer ACT2 to overlap the gate electrode, it is possible to minimize the amount of hydrogen (H) flowing into the upper semiconductor layer ACT2 during a subsequent heat treatment process and thereby to minimize the length of the offset region formed in the lower semiconductor layer ACT1, and the sufficient lower semiconductor layer ACT1 can ensure a channel region.

According to the embodiment of the present disclosure, by removing a portion of the upper semiconductor layer ACT2 which corresponds to an opening AOP during a transistor manufacturing process, it is possible to maximize the removal of hydrogen (H) present in a fine insulating film FI and thereby reduce deterioration and improve the reliability of the transistor.

According to the embodiment of the present disclosure, it is possible to minimize the influence of hydrogen (H) on the lower semiconductor layer ACT1 through the hydrogen gettering function of the fine insulating film FI positioned at between the upper semiconductor layer ACT2 and the lower semiconductor layer ACT1.

As apparent from the foregoing, according to the embodiment of the present disclosure, the active layer includes an upper semiconductor layer ACT2, a fine insulating film FI, and a lower semiconductor layer ACT1, and the upper semiconductor layer ACT2 includes an opening AOP in a portion overlapping the gate electrode, thereby minimizing defects in the lower semiconductor layer ACT1 and reducing deterioration due to shallow traps.

Specifically, according to the embodiment of the present disclosure, by providing a fine insulating film FI formed without a vacuum break on the lower semiconductor layer ACT1, it is possible to minimize the formation of defects in the lower semiconductor layer ACT1 forming a channel region, and thereby reduce deterioration due to traps and improve reliability of the transistor.

According to the embodiment of the present disclosure, by disposing the end adjacent to the opening AOP in the upper semiconductor layer ACT2 to overlap the gate electrode, it is possible to minimize the amount of hydrogen (H) flowing into the upper semiconductor layer ACT2 during a subsequent heat treatment process and thereby to minimize the length of the offset region formed in the lower semiconductor layer ACT1, and the sufficient lower semiconductor layer ACT1 can ensure a channel region.

According to the embodiment of the present disclosure, by removing a portion of an upper semiconductor layer ACT2 which corresponds to an opening AOP during a transistor manufacturing process, it is possible to maximize the removal of hydrogen (H) present in a fine insulating film FI and thereby reduce deterioration and improve reliability of the transistor.

According to the embodiment of the present disclosure, it is possible to minimize the influence of hydrogen (H) on the lower semiconductor layer ACT1 through the hydrogen gettering function of the fine insulating film FI positioned at between the upper semiconductor layer ACT2 and the lower semiconductor layer ACT1.

According to the embodiment of the present disclosure, it is possible to improve the power of transistors and reduce power consumption of display devices, thereby realizing ESG goals.

It will be apparent to those skilled in the art that various modifications and variations may be made in the present disclosure without departing from the spirit or scope of the disclosure. Thus, it is intended that the present disclosure covers the modifications and variations of the present disclosure provided they fall within the scope of the appended claims and their equivalents.

What is claimed is:

1. A display device, comprising:
a substrate;
an active area and a non-active area;
a transistor disposed at least in the active area and comprising a gate electrode, a source electrode, a drain electrode, and an active layer; and
a gate insulating film disposed between the gate electrode and the active layer,
wherein the active layer comprises:
a lower semiconductor layer positioned adjacent to the substrate and having a channel region and source-drain regions positioned at both sides of the channel region interposed between the source-drain regions;
an upper semiconductor layer adjacent to the gate electrode and positioned on the lower semiconductor layer; and
a fine insulating film positioned between the lower semiconductor layer and the upper semiconductor layer,
wherein the upper semiconductor layer comprises an opening in a portion overlapping the gate electrode, and the fine insulating film and the gate insulating film contact each other through the opening.

2. The display device according to claim 1, wherein the upper semiconductor layer overlaps the source-drain regions of the lower semiconductor layer and is not disposed in the opening.

3. The display device according to claim 1, wherein a width of the opening is smaller than a width of the gate electrode.

4. The display device according to claim 1, wherein an end of the upper semiconductor layer adjacent to the opening overlaps the gate electrode.

5. The display device according to claim 1, wherein a thickness of the fine insulating film is less than a thickness of the lower semiconductor layer and a thickness of the upper semiconductor layer.

6. The display device according to claim 1, wherein a thickness of the fine insulating film is less than a thickness of the gate insulating film.

7. The display device according to claim 1, wherein a thickness of the lower semiconductor layer is greater than a thickness of the upper semiconductor layer.

8. The display device according to claim 1, wherein the fine insulating film comprises a dielectric material.

9. The display device according to claim 1, wherein the fine insulating film comprises at least one of silicon oxide (SiOx) and silicon oxynitride (SiOxNy).

10. The display device according to claim 1, wherein an end of the upper semiconductor layer adjacent to the opening is inclined.

11. The display device according to claim 1, wherein a distance from an upper surface of the fine insulating film exposed to the opening to the gate electrode is less than a distance from the upper surface of the fine insulating film positioned outside the gate electrode to an upper surface of the gate insulating film.

12. The display device according to claim 1, wherein the source electrode and the drain electrode penetrate the upper semiconductor layer and the fine insulating film, and contact the source-drain regions of the lower semiconductor layer.

13. The display device according to claim 1, wherein the upper semiconductor layer and the lower semiconductor layer comprise an oxide semiconductor.

14. The display device according to claim 1, wherein the transistor is further disposed in the non-active area of the substrate.

15. A transistor, comprising:
an active layer;
a gate electrode overlapping the active layer;
a gate insulating film disposed between the active layer and the gate electrode; and
a source electrode and a drain electrode contacting source-drain regions of the active layer,
wherein the active layer comprises:
a lower semiconductor layer positioned adjacent to a substrate;
an upper semiconductor layer positioned adjacent to the gate electrode; and
a fine insulating film disposed between the lower semiconductor layer and the upper semiconductor layer, and
wherein the upper semiconductor layer comprises an opening in a portion overlapping the gate electrode, and the fine insulating film and the gate insulating film contact each other through the opening.

16. The transistor according to claim 15, wherein the upper semiconductor layer overlaps the source-drain regions of the lower semiconductor layer and is not disposed in the opening.

17. The transistor according to claim 15, wherein a width of the opening is less than a width of the gate electrode.

18. The transistor according to claim 15, wherein an end of the upper semiconductor layer adjacent to the opening overlaps the gate electrode.

19. The transistor according to claim 15, wherein a thickness of the fine insulating film is less than a thickness of the lower semiconductor layer, and the thickness of the fine insulating film is less than a thickness of the upper semiconductor layer.

20. The transistor according to claim 15, wherein the source electrode and the drain electrode penetrate the upper semiconductor layer and the fine insulating film, and contact the source-drain regions of the lower semiconductor layer.
